(19) United States
(12) Patent Application Publication
(10) Pub. No.: US 2021/0408191 A1
(43) Pub. Date: Dec. 30, 2021

(54) DISPLAY PANEL AND ELECTRONIC DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yong ZHAO, Wuhan, Hubei (CN); Zuomin LIAO, Wuhan, Hubei (CN); Tao CHEN, Wuhan, Hubei (CN)

(21) Appl. No.: 16/652,558

(22) PCT Filed: Dec. 23, 2019
(86) PCT No.: PCT/CN2019/127481

§ 371 Date: Mar. 31, 2020

(30) Foreign Application Priority Data
Aug. 9, 2019 (CN) 201910736563.X

(51) Int. Cl. H01L 27/32

(52) U.S. Cl. CPC H01L 27/3262; H01L 27/1214; H01L 27/3248

(57) ABSTRACT

The present application provides a display panel and an electronic device, wherein by setting a ratio of a vertical distance from a center point of the additional functional area to one of the first side and the third side to a vertical distance between the first side and the third side ranging from 1/10 to 1/2 and a ratio of a vertical distance from the center point of the additional functional area to one of the second side and fourth side to a vertical distance between the second side and fourth side ranging from 1/10 to 1/2.

### BACKGROUND OF INVENTION

### Field of Invention

The present application relates to a field of display technology, and in particular, to a display panel and an electronic device.

### Description of Prior Art

At present, a front camera of a smart mobile terminal such as a mobile phone is placed on a top of a screen of the smart mobile terminal. Based on this design, image of the first user displayed on the smart mobile terminal of a second user fails to provide a face-to-face head-up use effect of a second user and a first user when the first user uses the front camera to perform video communication with the second user, resulting in a poor video communication experience.

Therefore, there is a need to propose a technical solution to solve the problem that the front camera placed on the top of the screen of the smart mobile terminal results a poor video communication experience for the users.

An object of the present application is to provide a. display panel and an electronic device to solve the problem that the traditional smart mobile terminal cannot provide users with a head-up experience during video communication.

### SUMMARY OF INVENTION

In order to achieve the above object, the present application provides a display panel including at least one additional functional area and a main display area located at a periphery of the additional functional area, wherein

the display panel includes a first side, a second side, a third side, and a fourth side, the first side is opposite to the third side, the second side is opposite to the fourth side, the second side is connected between the first side and the third side, and the fourth side is connected between the first side and the third side;

a ratio of a vertical distance from a center point of the additional functional area to one of the first side and the third side to a vertical distance between the first side and the third side ranges from 1/10 to 1/2; and

a ratio of a vertical distance from the center point of the additional functional area to one of the second side and fourth side to a. vertical distance between the second side and fourth side ranges from 1/10 to 1/2.

In the display panel, the ratio of the vertical distance from the center point of the additional functional area to one of the first side and the third side to the vertical distance between the first side and the third side ranges from 1/8 to 1/2.

in the display panel, the ratio of the vertical distance from the center point of the additional functional area to one of the first side and the third side to the vertical distance between the first side and the third side ranges from 1/3 to 2/5.

In the display panel, the ratio of the vertical distance from the center point of the additional functional area to one of the second side and fourth side to the vertical distance between the second side and fourth side ranges from 1/8 to 1/2.

In the display panel, the ratio of the vertical distance from the center point of the additional functional area to one of the second side and fourth side to the vertical distance between the second side and fourth side ranges from 1/3 to 2/5.

In the display panel, a light transmittance of the additional functional area is greater than a light transmittance of the main display area.

in the display panel, the light transmittance of the additional functional area is greater than 30%, and the light transmittance of the main display area is less than 30%.

In the display panel, the additional functional area has at least one light-transmitting area, the light-transmitting area is provided with a plurality of first display pixels, and the display panel further includes: a plurality of first pixel driving circuits disposed at a periphery of the light-transmitting area and configured to drive the plurality of first display pixels to emit light.

In the display panel, the display panel further includes a plurality of first signal lines and a plurality of second signal lines, the plurality of first signal lines and the plurality of second signal lines are electrically connected to the plurality of first pixel driving circuits, and the plurality of the first signal lines and the plurality of the second signal lines are all disposed at the periphery of the light-transmitting area,

In the display panel, the plurality of first pixel driving circuits are electrically connected to the plurality of first display pixels through a plurality of transparent wires to drive the plurality of first display pixels to emit light.

In the display panel, the plurality of transparent wires are arranged in at least two layers.

In the display panel, an area of the light-transmitting area ranges from 0.36 mm² to 100 mm².

In the display panel, the additional functional area has one of the light-transmitting area.

In the display panel, the plurality of first pixel driving circuits constitute at least one pixel driving circuit island and are disposed at the periphery of the light-transmitting area.

In the display panel, the pixel driving circuit island includes an m×n array of the first pixel driving circuits, m represents a number of rows of the first pixel driving circuits, n represents a number of columns of the first pixel driving circuits, m and n are both positive integers, and at least one of m and n is greater than 1.

In the display panel, the main display area is provided with a plurality of second display pixels, and each of the second display pixels includes at least three second sub-pixels; the main display area is provided with a plurality of second pixel driving circuits, and each of the second pixel driving circuits correspondingly drives one of the second sub-pixels; and an area that each of the first pixel driving circuits occupies the display panel is smaller than an area that each of the second pixel driving circuits occupies the display panel.

In the display panel, a sum of areas of devices of each of the first pixel driving circuits is smaller than a sum of areas of devices of each of the second pixel driving circuits; and/or a sum of a number of the devices of each of the first pixel driving circuits is smaller than a sum of a number of the devices of each of the second pixel driving circuits; and/or an average area of wirings of each of the first pixel driving circuits is less than an average area of wirings of each of the second pixel driving circuits, wherein the devices include at least one of a switching unit and a capacitor, and the wirings include a plurality of signal traces.

In the display panel, the additional functional area is at least one of a camera area, an optical touch area, and an optical fingerprint recognition area.

An electronic device including a display panel and a photosensitive unit, and the display panel includes: at least one additional functional area and a main display area located at a periphery of the additional functional area, wherein

the display panel includes a first side, a second side, a third side, and a fourth side, the first side is opposite to the third side, the second side is opposite to the fourth side, the second side is connected between the first side and the third side, and the fourth side is connected between the first side and the third side;

a ratio of a vertical distance from a center point of the additional functional area to one of the first side and the third side to a vertical distance between the first side and the third side ranges from 1/10 to 1/2.;

a ratio of a vertical distance from the center point of the additional functional area to one of the second side and fourth side to a vertical distance between the second side and fourth side ranges from 1/10 to 1/2; and

the photosensitive unit is disposed on one side of the display panel correspondingly to the additional functional area.

In the electronic device, the light transmittance of the additional functional area is greater than 50%, and the light transmittance of the main display area is less than 20%.

The present application provides a display panel and an electronic device, wherein by setting a ratio of a vertical distance from a center point of the additional functional area to one of the first side and the third side to a vertical distance between the first side and the third side ranging from 1/10 to 1/2 and a ratio of a vertical distance from the center point of the additional functional area to one of the second side and fourth side to a vertical distance between the second side and fourth side ranging from 1/10 to 1/2, when the photosensitive unit located on a side of the display panel and corresponding to the additional functional area is served as a camera, users can use the camera to provide a head-up experience during video communication.

### BRIEF DESCRIPTION OF DRAWINGS

FIG. 1 is a schematic plan view of a display panel according to an embodiment of the present application.

FIG. 2 is a first partial enlarged view of the display panel shown in FIG. 1.

FIG. 3 is a second partial enlarged view of the display panel shown in FIG. 1.

FIG. 4A is a partially enlarged view of the display panel shown in FIG. 2.

FIG. 4B is a first cross-sectional view of the display panel shown in FIG. 4A.

FIG. 4C is a second cross-sectional view of the display panel shown in FIG. 4A.

FIG. 4D is a third cross-sectional view of the display panel shown in FIG. 4A.

FIG. 4E is a fourth cross-sectional view of the display panel shown in FIG. 4A.

FIG. 4F is a fifth cross-sectional view of the display panel shown in FIG. 4A.

FIG. 5 is a schematic diagram of a first pixel driving circuit of the present application.

Elements in the drawings are designated by reference numerals listed below.

100 display panel; 100a main display area; 100b additional functional area; 100c light-transmitting area; P1 first display pixel; 1001 first side; 1002 second side; 1003 third side; 1004 fourth side; A center point; P1 first display pixel; 101 substrate; 1021 first pixel driving circuit; 1022 second pixel driving circuit; 103 insulating layer; 1031 first insulating layer; 1032 second insulating layer; 1033 third insulating layer; four insulating layers; 104 transparent wire; 1041 first transparent wire; 1042 second transparent wire; 1043 third transparent wires; 1051 first anode; 1052 second anode; 1061 first sub-pixel; 1062 second sub-pixel; 107 pixel definition layer; 102A pixel driving circuit island; Vdd first power signal line; DTFT driving transistor; STFT1 first switching transistor; Cap storage capacitor; D data line; S scan line.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

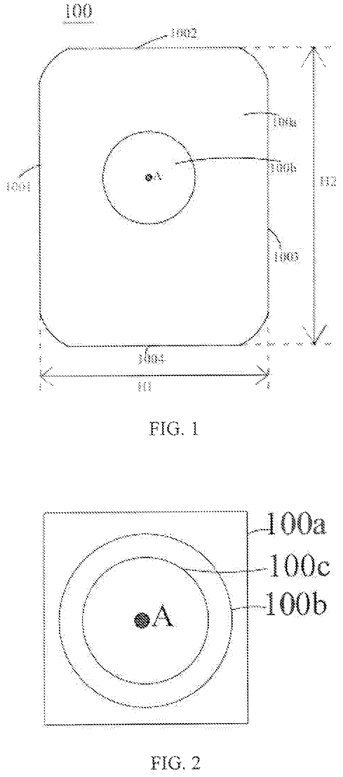

Refer to FIG. 1, which is a schematic plan view of a display panel according to an embodiment of the present application. The display panel 100 includes at least one additional functional area 100b and a main display area 100a located at a periphery of the additional functional area 100b. The main display area. 100a and the additional functional area 100b of the display panel 100 are both provided with pixels for full-screen display.

The display panel includes a first side 1001, a second side 1002, a third side 1003, and a fourth side 1004. The first side 1001 is opposite to the third side 1003. The second side 1002 is disposed opposite the fourth side 1004. The second side 1002 is connected between the first side 1001 and the third side 1003. The fourth side 1004 is connected between the first side 1001 and the third side 1003. The first side 1001 and the third side 1003 are parallel to each other and have the same length. The second side 1002 and the fourth side 1004 are parallel to each other and have the same length. A corner between adjacent ones of the sides can be a right angle or an arc angle. Specifically, the corner between adjacent ones of the sides is an arc angle.

The additional functional area 100b is a light-transmitting area, that is, the additional functional area 100b can display an image, and a photosensitive unit can also be provided on one side of the display panel 100 corresponding to the additional functional area 100b, so that the display panel 100 has additional functions. The additional functional area 100b may be a camera area, that is, when the photosensitive unit is served as a camera, the display panel 100 may be applied to an electronic device having a photographing function. The additional functional area 100b may also be an optical touch area, that is, the photosensitive unit is an optical touch component, and the display panel 100 may be applied to an electronic device having an optical touch function. Alternatively, the additional functional area 100b may also be an optical fingerprint identification area, that is, the photosensitive unit is an optical fingerprint device, and the display panel 100 may be applied to an electronic device having an optical fingerprint identification function. Also, the additional functional area 100b may be a set of at least two of a camera area, an optical touch area, and an optical fingerprint identification area. The additional functional area 100b may have a shape of a square, a circle, or an irregular shape. A number of the additional functional areas 100b may be one or two or more. The plurality of additional functional areas 100b may be provided collectively or dispersedly. In order to facilitate the description of the technical solution of the present application, the number of additional functional areas 100b is set to one for exemplary.

A ratio of a vertical distance from a center point A of the additional functional area 100b to one of the first side 1001 and the third side 1003 to a vertical distance H1 between the first side 1001 and the third side 1003 ranges from 1/10 to 1/2. A ratio of a vertical distance from the center point A of the additional functional area 100b to one of the second side 1002 and fourth side 1004 to a vertical distance H2 between the second side 1002 and fourth side 1004 ranges from 1/10 to 1/2. By setting the ratios of the vertical distances from the center point A of the additional functional area 100b to different ends of the display panel 100 to the size of the display panel 100 to specific values, when the photosensitive unit located on a side of the display panel 100 and corresponding to the additional functional area 100b is served as a camera, users can use the camera to provide a head-up experience during video communication.

In an embodiment of the present application, by setting a ratio of a vertical distance from a center point of the additional functional area to one of the first side and the third side to a vertical distance between the first side and the third side ranging from 1/10 to 1/2 and a ratio of a vertical distance from the center point of the additional functional area to one of the second side and fourth side to a vertical distance between the second side and fourth side ranging from 1/10 to 1/2, when the photosensitive unit located on a side of the display panel and corresponding to the additional functional area is served as a camera, users can use the camera to provide a head-up experience during video communication.

The ratio of the vertical distance from the center point A of the additional functional area 100b to one of the first side 1001 and the third side 1003 to the vertical distance H1 between the first side 1001 and the third side 1003 ranges from 1/8 to 1/2. For example, ratio of the vertical distance from the center point A of the additional functional area 100b to one of the first side 1001 and the third side 1003 to the vertical distance H1 between the first side 1001 and the third side 1003 is 1/6, 1/5, 11/30, or 2/5, etc., so that when a camera located on one side of the display panel 100 and corresponding to the additional functional area 100b images, users can use the camera to provide a great head-up experience during video communication. Further, ratio of the vertical distance from the center point A of the additional functional area 100b to one of the first side 1001 and the third side 1003 to the vertical distance H1 between the first side 1001 and the third side 1003 ranges from 1/3 to 2/5, so that when a camera located on one side of the display panel 100 and corresponding to the additional functional area 100b images, users can use the camera to further provide a great head-up experience during video communication.

The ratio of the vertical distance from the center point A of the additional functional area 100b to one of the second side 1002 and fourth side 1004 to the vertical distance H2 between the second side 1002 and fourth side 1004 ranges from 1/8 to 1/2. For example, the ratio of the vertical distance from the center point A of the additional functional area 100b to one of the second side 1002 and fourth side 1004 to the vertical distance H2 between the second side 1002 and fourth side 1004 is 1/6, 1/5, 100, or 2/5, etc., so that when a camera located on one side of the display panel 100 and corresponding to the additional functional area 100b images, users can use the camera to provide a great head-up experience during video communication. Further, the ratio of the vertical distance from the center point A of the additional functional area 100b to one of the second side 1002 and fourth side 1004 to the vertical distance H2 between the second side 1002 and fourth side 1004 ranges from 1/3-2/5, so that when a camera located on one side of the display panel 100 and corresponding to the additional functional area 100b images, users can use the camera to further provide a great head-up experience during video communication.

Further, the light transmittance of the additional functional area 100b is greater than the light transmittance of the main display area 100a, so that the photosensitive unit located on a side of the additional functional area 100b and corresponding to the additional functional area 100b can receive more light signals, and when the photosensitive unit is served as a camera, the camera can receive more light signals to improve the imaging effect of the camera.

The light transmittance of the additional functional area 100b is greater than 30%, and the light transmittance of the main display area 100a is less than 30%, that is, the additional functional area 100b is a high light-transmitting area, and the main display area 100a is a low light-transmitting area. The light transmittance of the main display area 100a is less than 30%, which is beneficial to be installed in more driving circuits or traces with a light-shielding metal layer, in order to correspondingly set more pixels in the main display area 100a to improve the display effect, The light transmittance of the additional functional area 100b is greater than 30%, so that the additional functional area 100b can display while meeting the basic light transmission requirements.

Further, the light transmittance of the additional functional area 100b is greater than 50%, and the light transmittance of the main display area 100a is less than 20%. For example, the light transmittance of the additional functional area 100b is 70%, 80%, or 90%, and the light transmittance of the main display area 100a is 15% or 10%. The light transmittance of the additional functional area 100b is greater than 50%, so that the camera can receive more light signals to improve the imaging effect of the camera, and when the photosensitive unit is served as a camera, it can have a better imaging effect. The light transmittance of the main display area 100a is less than 20%, which is conducive to providing more opaque metal layers in the main display area 100a, and correspondingly set more pixels to improve the display effect.

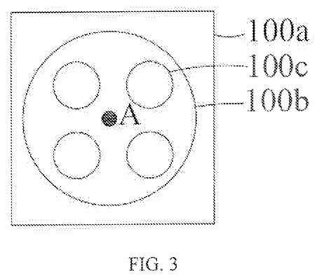

Refer to FIG. 2 and FIG. 3. FIG. 2 is a first partial enlarged view of the display panel shown in FIG. 1, and FIG. 3 is a second partial enlarged view of the display panel shown in FIG. 1. Each of the additional functional areas 100b has at least one light-transmitting area 100c. As shown in FIG. 2, the additional functional area 100b may have a light-transmitting area 100c, and the light-transmitting area 100c may be located in the additional functional area 100b, that is, a size of the light-transmitting area 100c is smaller than a size of the additional functional area 100b. Alternatively, the additional functional area 100b can completely coincide with the light-transmitting area 100c. As shown in FIG. 3, the additional functional area 100b may also have a plurality of light-transmitting areas 100c. The plurality of light-transmitting areas 100c are uniformly and regularly disposed in the additional functional area 100b, and an area between adjacent ones of the light-transmitting areas 100c can be transparent or opaque. The additional functional area 100b may be a circular area, a rectangular area, or the like. The light-transmitting area 100c may be a regular area, such as an axisymmetric area including a square area, a triangular area, an oval area, a circular area, and the like. The light-transmitting area 100c may also be an irregular area. Specifically, the additional functional area 100b has a light-transmitting area 100c.

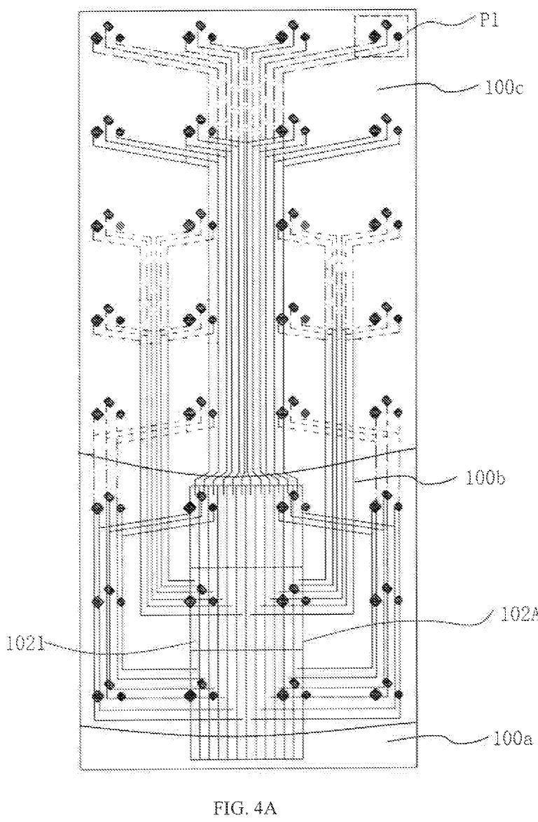

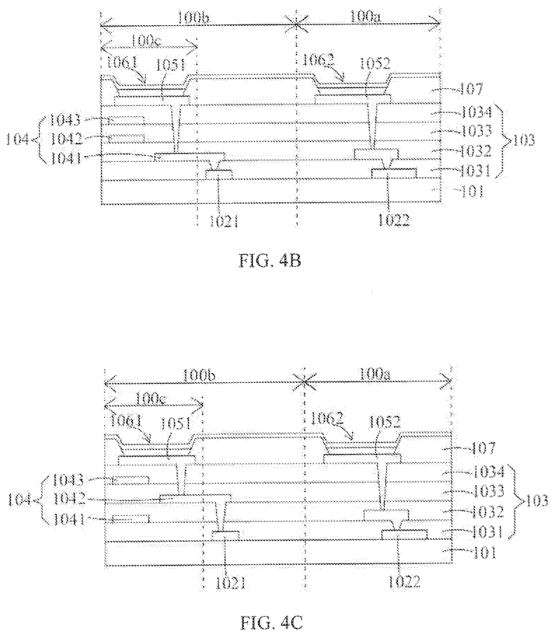

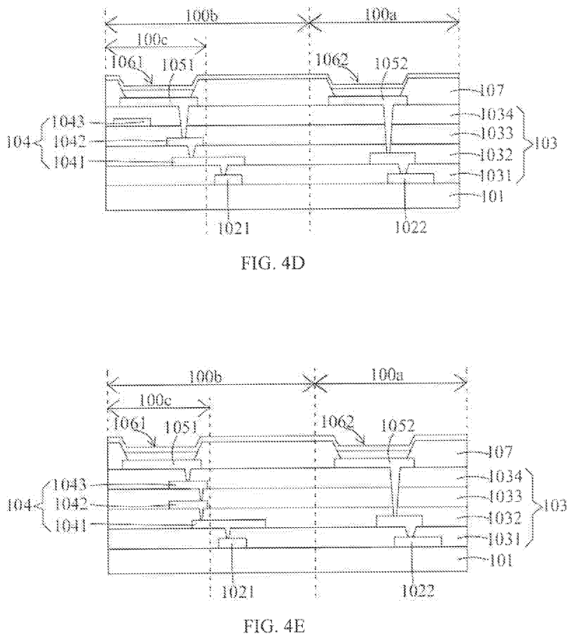

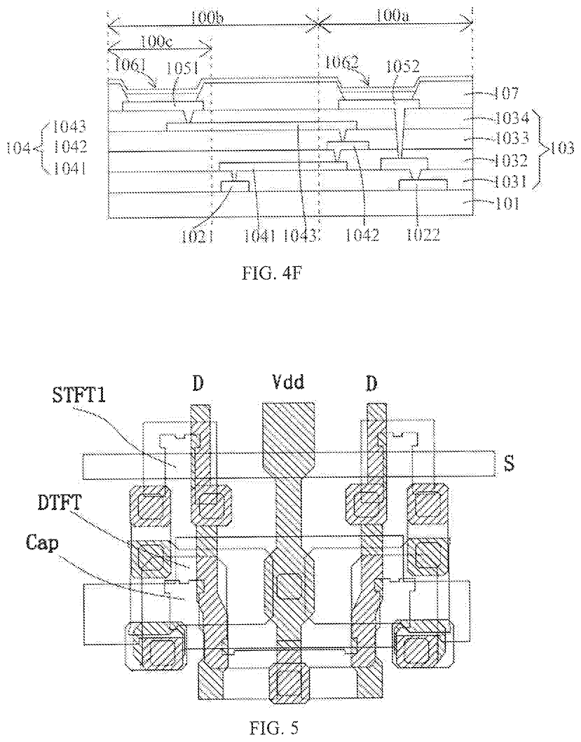

Refer to FIG. 4A and FIG. 4B. FIG. 4A is a partial enlarged view of the display panel shown in FIG. 2, and FIG. 4B is a first cross-sectional view of the display panel shown in FIG. 4A. The display panel 100 has a main display area 100a and an additional functional area 100b. The additional functional area 100b has a light-transmitting area 100c, and the light-transmitting area 100c is located in the additional functional area 100b.

The main display area 100a is provided with a plurality of second display pixels (not shown), and each of the second display pixels includes at least three second sub-pixels 1062, such as a red second sub-pixel, a green second sub-pixel, and a blue second sub-pixel. Correspondingly, the main display area 100a is provided with a plurality of second pixel driving circuits 1022, and each of the second pixel driving circuits 1022 drives one of the second sub-pixels 1062 correspondingly. Each of the second sub-pixels 1062 includes a second anode 1052, and the second anode 1052 is a semi-transparent electrode or an opaque electrode. Each of the second pixel driving circuits 1022 is electrically connected to the second anode 1052 of each of the second sub-pixels 1062 through a conductive layer located between at least three insulating layers 103.

The light-transmitting area 100c is provided with a plurality of first display pixels P1, and each of the first display pixels P1 includes at least three first sub-pixels 1061, such as a red first sub-pixel, a green first sub-pixel, and a blue first pixel. Correspondingly, the display panel 100 further includes a plurality of first pixel driving circuits 1021. The plurality of first pixel driving circuits 1021 are disposed at a periphery of the light-transmitting area 100c and are configured to drive the plurality of first display pixels P1 to emit light. Each of the pixel driving circuits 1021 drives one of the first sub-pixels 1061 correspondingly. Each of the first sub-pixels 1061 includes a first anode 1051, and the first anode 1051 is a semi-transparent electrode or an opaque electrode. The plurality of first pixel driving circuits 1021 are disposed at a periphery of the light-transmitting area 100c, so that a size of the light-shielding metal layer of the light-transmitting area 100c is reduced, thereby increasing the light transmittance of the light-transmitting area 100c, which is beneficial the light transmission of the light-transmitting area 100c to be greater than the light transmittance of the main display area 100a.

An area of each of the light-transmitting areas 100c is 0.32 mm² to 120 mm², so as to ensure that when a camera is provided in the additional functional area 100b of the display panel 100, the camera can have a good photographing effect and reduce the process difficulty. The area of the light-transmitting area 100c less than 0.32 mm² will cause light interference phenomenon in the light-transmitting area 100c, which is not conducive to the imaging of the camera; while the area of the light-transmitting area 100c larger than 120 mm² will increase the process difficulty. For example, more wires need to be used to connect the first display pixels P1 and the first pixel driving circuits 1021 at the periphery of the light-transmitting area 100c, more wires set in the same layer increases the risk of a short circuit between adjacent ones of the wires, and more wires arranged in multiple layers increases the risk of poor electrical contact between adjacent ones of the wires, that is, the area of the light-transmitting area 100c larger than 120 mm² will increase the difficulty in the manufacturing process of the display panel 100. Further, an area of each of the light-transmitting areas 100c is 0.36 mm² to 100 mm², so as to further improve the photographing effect of the camera and reduce the difficulty in the manufacturing process of the display panel 100.

In each of the transparent areas 100c, a ratio of a sum of the areas of the first anodes 1051 of the plurality of first display pixels P1 to an area of the corresponding transparent area 100c is less than 50%, so as to ensure that the transparent area 100c has a sufficient light-transmitting area, thereby allowing the photosensitive unit to receive sufficient light signals, and when the photosensitive unit is served as a camera, it can have a good imaging effect. In each of the light-transmitting areas 100c, the ratio of the sum of the areas of the first anodes 1051 of the plurality of first display pixels P1 to the area of the corresponding light-transmitting area 100c is greater than 5% to ensure that the light-transmitting area 100c has sufficient first display pixels P1 for display. In each of the light-transmitting areas 100c, the ratio of the sum of the areas of the first anodes 1051 of the plurality of first display pixels P1 to the area of the corresponding light-transmitting area 100c ranges from 8% to 45% to achieve balance between the display function and light transmission function of the transparent area 100c.

The plurality of first pixel driving circuits 1021 may be all disposed in the additional functional area 100b and at the periphery of the light-transmitting area 100c. Also, the plurality of first pixel driving circuits 1021 may be all provided in the main display area 100a. Alternatively, the plurality of first pixel driving circuits 1021 may be partially disposed in the additional functional area 100b and at the periphery of the light-transmitting area 100c, and partially disposed in the main display area 100a. Also, the plurality of first pixel driving circuits 1021 may be dispersedly and regularly disposed at the periphery of the light-transmitting area 100c, or the plurality of first pixel driving circuits 1021 may be disposed collectively at the periphery of the light-transmitting area 100c.

As shown in FIG. 4A, the plurality of first pixel driving circuits 1021 constitute at least one pixel driving circuit island 102A and are disposed at the periphery of the light-transmitting area 100c. Each of the pixel driving circuit islands 102A is formed by a plurality of first pixel driving circuits 1021 disposed collectively. Each of the pixel driving circuit islands 102A includes an m×n array of the first pixel driving circuits, m represents a number of rows of the first pixel driving circuits 1021, n represents a number of columns of the first pixel driving circuits 1021, m and n are both positive integers, and at least one of m and n is greater than 1. A range of m is greater than 3 and less than 128, and a range of n is greater than or equal to 1 and less than 128. Further, a range of m is greater than or equal to 3 or less than 64, and a range of n is greater than or equal to 1 or less than 64. In each of the pixel driving circuit islands 102A, a distance between adjacent ones of the first pixel driving circuits 1021 is smaller than a distance between adjacent ones of the first display pixels P1, or a distance between adjacent ones of the first pixel driving circuits 1021 is 0.

The plurality of first pixel driving circuits 1021 are electrically connected to the plurality of first display pixels P1 through the plurality of transparent wires 104 to drive the plurality of first display pixels P1 to emit light, so as to prevent the light-transmitting area 100c from the introduction of light-shielding metal wires, thereby improving the light transmittance of the light-transmitting area 100c. Material for preparing the transparent wire 104 is selected from indium tin oxide, indium zinc oxide, or nano-silver wire.

The plurality of transparent wires 104 are arranged in at least two layers to increase the wiring space of the transparent wires 104 and avoid occurrence of short circuit between adjacent ones of the transparent wires 104 due to a narrow gap. The distance between adjacent ones of the transparent wires 104 in the same layer is greater than 2 micrometers, so as to avoid occurrence of short circuit between adjacent ones of the transparent wires 104 in the same layer. A width of each of the transparent wires 104 is greater than 1 micron, so as to prevent the transparent wire 104 from being easily broken or having a large impedance due to a narrow width of the transparent wire 104.

A plurality of transparent wires 104 are disposed between at least three insulating layers 103, The at least three insulating layers 103 cover a plurality of first pixel driving circuits 1021, a plurality of second pixel driving circuits 1022, and the substrate 101. The first sub-pixels 1061 of the plurality of first display pixels P1 and the second sub-pixels 1062 of the plurality of second display pixels are disposed on a side of the at least three insulating layers 103 away from the substrate 101. The first anode 1051 is electrically connected to the transparent wire 104 through a via hole located in the insulating layer 103, and the transparent wire 104 is electrically connected to the first pixel driving circuit 1021 through a via hole located in the insulating layer 104, so that the first sub-pixel 1061 is electrically connected to the first pixel driving circuit 1021. The insulating layers 103 may be organic insulating layers or inorganic insulating layers. Material for preparing the organic insulating layers is selected from polyimide or a photoresist. Material for preparing the inorganic insulating layers is selected from silicon nitride, silicon oxide, or silicon oxynitride.

A part of the first sub-pixels 1061 may be electrically connected to a part of the plurality of first pixel driving circuits 1021 in a one-to-one correspondence through the transparent wires 104 on one layer, and another part of the first sub-pixels 1061 may be electrically connected to another part of the plurality of first pixel driving circuits 1021 through the transparent wires 104 on another layer. Specifically, as shown in FIG. 4B, the plurality of transparent wires 104 include a first transparent wire 1041, a second transparent wire 1042, and a third transparent wire 1043 located in different layers. The second transparent wire 1042 and the third transparent wire 1043 are both located in the light-transmitting area 100c. The first transparent wire 1041 extends from the light-transmitting area 100c into the light-transmitting area 100c and is located in the additional functional area 100b. The at least three insulating layers 103 include a first insulating layer 1031, a second insulating layer 1032, a third insulating layer 1033, and a fourth insulating layer 1034. The first insulating layer 1031 covers the first pixel driving circuits 1021, the second pixel driving circuits 1022, and the substrate 101. The first transparent wires 1041 are disposed on the first insulating layer 1031. The second insulating layer 1032 covers the first transparent wires 1041 and the first insulating layer 1031. The second transparent wires 1042 are disposed on the second insulating layer 1032. The third insulating layer 1033 covers the second transparent wires 1042 and the second insulating layer 1032. The third transparent wires 1043 are disposed on the third insulating layer 1033. The fourth insulating layer 1034 covers the third transparent wires 1043 and the third insulating layer 1033. The first anodes 1051 and the second anodes 1052 are disposed on the fourth insulating layer 1034. The first anodes 1051 are disposed in the light-transmitting area 100c, and the second anodes 1052 are disposed in the main display area 100a. The pixel definition layer 107 covers the fourth insulating layer 1034, a partial edge area of the first anodes 1051, and a partial edge area of the second anodes 1052. The pixel definition layer 107 is provided with a first opening corresponding to each of the first anodes 1051, and provided with a second opening corresponding to each of the second anodes 1052. The first anodes 1051 are electrically connected to the first transparent wires 1041 through via holes communicated with each other in the fourth insulation layer 1034, the third insulation layer 1033, and the second insulation layer 1032. The first transparent wires 1041 are electrically connected to the first pixel driving circuit 1021 through the via holes in the first insulation layer 1031. As shown in FIG. 4C, it is a second cross-sectional view of the display panel shown in FIG. 2. The display panel shown in FIG. 4C is basically similar to the display panel shown in FIG. 4B, except that the first transparent wire 1041 and the third transparent wire 1043 are disposed in the light-transmitting area 100c, the second transparent wire 1042 extends from the light-transmitting area 100c into the light-transmitting area 100c and is located in the additional functional area 100b, the first anodes 1051 are electrically connected to the second transparent wires 1042 through the via holes communicated with each other in the fourth insulating layer 1034 and the third insulating layer 1033, and the second transparent wires 1042 are electrically connected to the first pixel driving circuit 1021 through the via holes communicated with each other in the second insulating layer 1032 and the first insulating layer 1031.

A part of the first sub-pixels 1061 may be electrically connected through at least two layers of the transparent wires 104. Specifically, as shown in FIG. 4D, it is a third cross-sectional view of the display panel shown in FIG. 4A. The display panel shown in FIG. 4D is similar to the display panel substrate shown in FIG. 4B, except that the first anodes 1051 are electrically connected to the second transparent wires 1042 through the via holes communicated with each other in the fourth insulating layer 1034 and the third insulating layer 1033, the second transparent wires 1042 are electrically connected to the first transparent wires 1041 through the via holes in the second insulating layer 1032, and the first transparent wires 1041 are electrically connected to the first pixel driving circuit 1021 through the via holes in the first insulating layer 1031. As shown in FIG. 4E, it is a fourth cross-sectional view of the display panel shown in FIG. 4A. The display panel shown in FIG. 4E is similar to the display panel shown in FIG. 4B, except that the first anodes 1051 are electrically connected to the third transparent wires 1043 through the via holes in the fourth insulating layer 1034, the third transparent wires 1043 are electrically connected to the second transparent wires 1042 through the via holes in the third insulating layer 1033, the second transparent wires 1042 are electrically connected to the first transparent wires 1041 through the via holes in the second insulating layer 1032, and the first transparent wires 1041 are electrically connected to the first pixel driving circuit 1021 through the via holes in the first insulating layer 1031.

A part of the first sub-pixels 1061 is electrically connected to the first pixel driving circuit 1021 through the transparent wires 104 located in the additional functional area 100b. A part of the first sub-pixels 1061 is electrically connected to the first pixel driving circuit 1021 through the transparent wires 104 located in the additional functional area 100b and the main display area 100a. By providing the transparent wires 104 in the main display area 100a to further increase the wiring space of the transparent wires 104, thereby preventing occurrence of short circuit between adjacent ones of the transparent wires 104 in the same layer. Specifically, as shown in FIG. 4B, FIG. 4C, FIG. 4D, and FIG. 4E, the first sub-pixels 1061 are electrically connected through the first transparent wires 1041, the second transparent wires 1042, and the third transparent wires 1043 located in the additional functional area 100b. As shown in FIG. 4F, it is a fifth cross-sectional view of the display panel shown in FIG. 4A. The display panel shown in FIG. 4F is basically similar to the display panel shown in FIG. 4E, except that the first transparent wire 1041 extends from the main display area 100a to the additional functional area 100b, the second transparent wire 1042 is located in the main display area 100a, and the third transparent wire 1043 extends from the main display area 100a to the light-transmitting area 100c. The first anode 1051 is electrically connected to the third transparent wire 1043 through a via hole in the fourth insulating layer 1034, the third transparent wire 1043 is electrically connected to the second transparent wire 1042 through a via hole in the third insulating layer 1033, the second transparent wire 1042 is electrically connected to the first transparent wire 1041 through a via hole in the second insulating layer 1032, and the first transparent wire 1041 is electrically connected to the first pixel driving circuit 1021 through a via hole in the first insulating layer 1031.

A pixel density of the first display pixels P1 of the light-transmitting area 100c may be smaller than a pixel density of the second display pixels of the main display area 100a, and/or, an interval between adjacent ones of the first display pixels P1 is larger than an interval between adjacent ones of the second display pixels, and/or, a size of the first display pixel 101 in the light-transmitting area 100c is smaller than a size of the second display pixel in the main display area 100a, so that the light transmittance of the light-transmitting area 100c is greater than the light transmittance of the main display area 100a. Further, the size of the first anode 1051 is smaller than the size of the second anode 1052, and/or, a size of the first opening of the pixel definition layer 107 corresponding to each of the first sub-pixels 1061 is smaller than a size of the second opening of the pixel definition layer 107 corresponding to each second sub-pixels 1062, so that the size of the first sub-pixel 1061 is smaller than the size of the second sub-pixel 1062, which is conducive to the size of the first display pixel P1 being smaller than the size of the second display pixel, so that the light transmittance of the light-transmitting area 100c is larger than that of the main display area 100a.

Each of the first pixel driving circuit 1021 and the second pixel driving circuit 1022 includes devices and wirings, wherein the devices include a switching element and a capacitor, and the wirings include a signal trace. The circuit design of the plurality of first pixel driving circuits 1021 is different from the circuit design of the plurality of second pixel driving circuits 1022 so that when the layout space of the display panel 100 is limited, the plurality of first pixel driving circuits 1021 may be provided at the periphery of the light-transmitting area 100c. Specifically, the area occupied by each of the first pixel driving circuits 1021 on the display panel 100 is smaller than the area occupied by each of the second pixel driving circuits 1022 on the display panel 100, so as to reduce the overall space occupied by the plurality of first pixel driving circuits 1021, and meanwhile, the light-transmitting area 100c can be designed larger.

Specifically, a sum of areas of devices of each of the first pixel driving circuits 1021 is smaller than a sum of areas of devices of each of the second pixel driving circuits 1022; and/or a sum of a number of the devices of each of the first pixel driving circuits 1021 is smaller than a sum of a number of the devices of each of the second pixel driving circuits 1022; and/or an average area of wirings of each of the first pixel driving circuits 1021 is less than an average area of wirings of each of the second pixel driving circuits 1022, wherein the devices include at least one of a switching unit and a capacitor, and the wirings include a plurality of signal traces.

The size of the devices in the first pixel driving circuit 1021 is smaller than the size of the devices in the second pixel driving circuit 1022, so that the sum of the areas of the devices of the first pixel driving circuit 1021 is smaller than the sum of the areas of the devices of the second pixel driving circuit 1022. For example, a size of the switching unit in the first pixel driving circuit 1021 is smaller than a size of the switching unit in the second pixel driving circuit 1022, and/or a size of the capacitor in the first pixel driving circuit 1021 is smaller than a size of the capacitor in the second pixel driving circuit 1022. At this time, the first pixel driving circuit 1021 and the second pixel driving circuit 1022 may use one of a 7T1C circuit, a 6T1C circuit, a 4T1C circuit, and a 2T1C circuit at the same time. The difference is that the size of the devices in the first pixel driving circuit 1021 is smaller than the size of the devices in the second pixel driving circuit 1022, wherein the 7T1C circuit includes 7 thin film transistors and 1 capacitor, the 6T1C circuit includes 6 thin film transistors and 1 capacitor, the 4T1C circuit includes 4 thin film transistors and 1 capacitor, and the 2T1C circuit includes two thin film transistors and a capacitor. The 7T1C circuit, the 6T1C circuit, the 4T1C circuit, and the 2T1C circuit all adopt a conventional design in the art, which the present application is not specifically limited.

The second pixel driving circuit 1022 uses the 7T1C circuit, the first pixel driving circuit 1021 uses at least one of the 2T1C circuit, the 4T1C circuit, and the 6T1C circuit. Alternatively, the second pixel driving circuit 1022 uses the 6T1C circuit, and the first pixel driving circuit 1021 uses at least one of the 4T1C circuit and the 2T1C circuit. Alternatively, the second pixel driving circuit 1022 uses the 4T1C circuit, and the first pixel driving circuit 1021 uses the 2T1C circuit so that a sum of a number of devices in each of the first pixel driving circuit 1021 is less than a sum of a number of devices in each of the second pixel driving circuits 1022.

Adjacent ones of the first pixel driving circuits 1021 share at least one signal trace, and adjacent ones of the first pixel driving circuits 1021 are mirror-symmetrically arranged with respect to one signal trace, and the signal trace includes a power signal trace so that an average wiring area occupied by each of the first pixel driving circuits 1021 is smaller than an average wiring area occupied by each of the second pixel driving circuits 1022. With decrease in the wiring areas of the plurality of first pixel driving circuits 1021, the area occupied by the plurality of fast pixel driving circuits 1021 on the display panel 100 is further reduced, which is more conducive to farther increasing the size of the display light-transmitting area 100c. Specifically, as shown in FIG. 5, it is a schematic diagram of a first pixel driving circuit of the present application. The first pixel driving circuits 1021 use the 2T1C circuit, wherein adjacent ones of the first pixel driving circuits 1021 share a first power supply signal line Vdd, and the driving transistors DTFT, the first switching transistor STFT1, and the storage capacitors Cap of adjacent ones of the first pixel driving circuits 1021 are disposed symmetrically on opposite sides of the first power signal trace Vdd, respectively, so as to reduce the total number of wirings required for the plurality of first pixel driving circuits 1021. In addition, adjacent ones of the first pixel driving circuits 1021 are arranged mirror-symmetrically, which is beneficial to reducing the overall space occupied by the first pixel driving circuits 1021. Since the second pixel driving circuits 1022 of the main display area 100a adopt a conventional design, the average wiring area of each of the first pixel driving circuits 1021 is smaller than the average wiring area of each of the second pixel driving circuits 1022.

The display panel 100 further includes a plurality of first signal lines (not shown) and a plurality of second signal lines (not shown), The plurality of first signal lines and the plurality of second signal lines are configured to load different electrical signals to the plurality of first pixel driving circuits 1021, thereby controlling the first display pixel P1 to emit light. The plurality of first signal lines and the plurality of second signal lines are electrically connected to the plurality of first pixel driving circuits 1021, and the plurality of first signal lines and the plurality of second signal lines are disposed at the periphery of the light-transmitting area 100c. When the light-transmitting area 100c is located in the additional functional area 100b, the plurality of first signal lines and the plurality of second signal lines may be disposed in the additional functional area 100b and at the periphery of the light-transmitting area 100c, or the plurality of first signal lines and the plurality of second signal lines may be disposed at a periphery of the additional functional area 100b. Each of the plurality of first signal lines is at least one of a scan line and a reset line. Each of the plurality of the second signal lines is a data line. The plurality of first signal lines and the plurality of second signal lines are disposed at the periphery of the light-transmitting area 100c to further increase the light transmittance of the light-transmitting area 100c.

The present application also provides an electronic device including the above display panel and a photosensitive unit. The photosensitive unit is disposed on one side of the display panel and is provided corresponding to an additional functional area. The photosensitive unit may be a camera, an optical touch component, a fingerprint recognition sensor, or the like. Specifically, the photosensitive unit is served as a camera. The electronic device may be a device with a single camera, a device with a dual camera, or a device with multiple cameras.

The present application provides the electronic device, wherein by setting a ratio of a vertical distance from a center point of the additional functional area to one of the first side and the third side to a vertical distance between the first side and the third side ranging from 1/10 to 1/2 and a ratio of a vertical distance from the center point of the additional functional area to one of the second side and fourth side to a vertical distance between the second side and fourth side ranging from 1/10 to 1/2, when the photosensitive unit located on a side of the display panel and corresponding to the additional functional area is served as a camera, users can use the camera to provide a head-up experience during video communication.

Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A display panel, comprising at least one additional functional area and a main display area located at a periphery of the additional functional area, wherein
the display panel comprises a first side, a second side, a third side, and a fourth side, the first side is opposite to the third side, the second side is opposite to the fourth side, the second side is connected between the first side and the third side, and the fourth side is connected between the first side and the third side;
a ratio of a vertical distance from a center point of the additional functional area to one of the first side and the third side to a vertical distance between the first side and the third side ranges from 1/10 to 1/2; and
a ratio of a vertical distance from the center point of the additional functional area to one of the second side and fourth side to a vertical distance between the second side and fourth side ranges from 1/10 to 1/2.

2. The display panel according to claim 1, wherein the ratio of the vertical distance from the center point of the additional functional area to one of the first side and the third side to the vertical distance between the first side and the third side ranges from 1/8 to 1/2.

3. The display panel according to claim 2, wherein the ratio of the vertical distance from the center point of the additional functional area to one of the first side and the third side to the vertical distance between the first side and the third side ranges from 1/3 to 2/5.

4. The display panel according to claim 1, wherein the ratio of the vertical distance from the center point of the additional functional area to one of the second side and fourth side to the vertical distance between the second side and fourth side ranges from 1/8 to 1/2.

5. The display panel according to claim 4, wherein the ratio of the vertical distance from the center point of the additional functional area to one of the second side and fourth side to the vertical distance between the second side and fourth side ranges from 1/3 to 2/5.

6. The display panel according to claim 1, wherein a light transmittance of the additional functional area is greater than a light transmittance of the main display area.

7. The display panel according to claim 6, wherein the light transmittance of the additional functional area is greater than 30%, and the light transmittance of the main display area is less than 30%.

8. The display panel according to claim 1, wherein the additional functional area has at least one light-transmitting area, the light-transmitting area is provided with a plurality of first display pixels, and the display panel further comprises: a plurality of first pixel driving circuits disposed at a periphery of the light-transmitting area and configured to drive the plurality of first display pixels to emit light.

9. The display panel according to claim 8, wherein the display panel further comprises a plurality of first signal lines and a plurality of second signal lines, the plurality of first signal lines and the plurality of second signal lines are electrically connected to the plurality of first pixel driving circuits, and the plurality of the first signal lines and the plurality of the second signal lines are all disposed at the periphery of the light-transmitting area.

10. The display panel according to claim 8, wherein the plurality of first pixel driving circuits are electrically connected to the plurality of first display pixels through a plurality of transparent wires to drive the plurality of first display pixels to emit light.

11. The display panel according to claim 10, wherein the plurality of transparent wires are arranged in at least two layers.

12. The display panel according to claim 8, wherein an area of the light-transmitting area ranges from 0.36 mm2 to 100 mm2.

13. The display panel according to claim 8, wherein the additional functional area has one of the light-transmitting area.

14. The display panel according to claim 8, wherein the plurality of first pixel driving circuits constitute at least one pixel driving circuit island and are disposed at the periphery of the light-transmitting area.

15. The display panel according to claim 14, wherein the pixel driving circuit island comprises an m×n array of the first pixel driving circuits, n represents a number of rows of the first pixel driving circuits, n represents a number of columns of the first pixel driving circuits, m and n are both positive integers, and at least one of m and n is greater than 1.

16. The display panel according to claim 8, wherein
the main display area is provided with a plurality of second display pixels, and each of the second display pixels comprises at least three second sub-pixels;
the main display area is provided with a plurality of second pixel driving circuits, and each of the second pixel driving circuits correspondingly drives one of the second sub-pixels; and
an area that each of the first pixel driving circuits occupies the display panel is smaller than an area that each of the second pixel driving circuits occupies the display panel.

17. The display panel according to claim 16, wherein
a sum of areas of devices of each of the first pixel driving circuits is smaller than a sum of areas of devices of each of the second pixel driving circuits; and/or
a sum of a number of the devices of each of the first pixel driving circuits is smaller than a sum of a number of the devices of each of the second pixel driving circuits; and/or
an average area of wirings of each of the first pixel driving circuits is less than an average area of wirings of each of the second pixel driving circuits, wherein the devices comprise at least one of a switching unit and a capacitor, and the wirings comprise a plurality of signal traces.

18. The display panel according to claim 1, wherein the function additional area is at least one of a camera area, an optical touch area, and an optical fingerprint recognition area.

19. An electronic device, wherein the electronic device comprises a display panel and a photosensitive unit, and the display panel comprises:
at least one additional functional area and a main display area located at a periphery of the additional functional area, wherein
the display panel comprises a first side, a second side, a third side, and a fourth side, the first side is opposite to the third side, the second side is opposite to the fourth side, the second side is connected between the first side and the third side, and the fourth side is connected between the first side and the third side;
a ratio of a vertical distance from a center point of the additional functional area to one of the first side and the third side to a vertical distance between the first side and the third side ranges from 1/10 to 1/2;
a ratio of a vertical distance from the center point of the additional functional area to one of the second side and fourth side to a vertical distance between the second side and fourth side ranges from 1/10 to 1/2; and
the photosensitive unit is disposed on one side of the display panel correspondingly to the function additional area.

20. The electronic device according to claim 19, wherein the light transmittance of the additional functional area is neater than 50%, and the light transmittance of the main display area is less than 20%.
